(19) United States
(12) Patent Application Publication
(10) Pub. No.: US 2010/0195277 A1
(43) Pub. Date: Aug. 5, 2010

(54) Dual Layer Printed Circuit Board

(75) Inventors: Xiaorong XUE, Shanghai (CN); Xuan JI, Shanghai (CN)

Correspondence Address: DLA PIPER LLP (US ), 2000 UNIVERSITY AVENUE, EAST PALO ALTO, CA, 94303-2248, US

(73) Assignee: Trident Microsystems, Inc., Santa Clara, CA (US)

(21) Appl. No.: 12/366,594

(22) Filed: Feb. 5, 2009

(51) Int. Cl. H05K 7/00; H01S 4/00

(52) U.S. Cl. 361/679.32; 29/592.1; 361/760

(57) ABSTRACT

Memory systems are disclosed which are comprised of a two or dual layer printed circuit board. Attached to the top layer of the dual layer printed circuit board are a memory chip and a memory controller with aligned, optimistic pin outs that optimized signal integrity layouts between certain high speed pins in a single layer. A set of high speed lines, including the data lines, that do not include any vias connect certain of the pins of the memory controller to certain of the pins of the memory chip. The high speed lines are covered by a sub-PCB that includes a copper lay that extends a ground or electrical plane above the top layer of the dual layer printed circuit board.

### TECHNICAL FIELD

The present innovations herein relate to memory module design, and more particularly, to two layer printed circuit boards incorporated into memory modules and designed with aspects to reduce crosstalk of memory signals and improve memory signal quality.

### BACKGROUND OF THE INVENTION

Second generation double data rate two synchronous dynamic random access memory (DDR2 SDRAM) is a device standard for a type of electronic memory. It is broadly used in electronics and computing devices, and is part of a family of memory. It improves on predecessors in the family primarily by operating at a higher speed. DDR2 typically operates at data transfer rates between about 400 million bits per second (MB/s) and 1066 MB/s.

Memory such as DDR2 is typically incorporated into a system by including a DDR2 chip on a printed circuit board (PCB) which may be integrated with other components more easily that the DDR2 package. At the data transfer rates described above, however, numerous design considerations should be followed in order to allow correct functioning of the module. Timing and delay matching issues are an important part of the design of a module including the DDR2 chip and its attached PCB. Layout of signal lines on the PCB should be done appropriately to prevent a situation where the lines interfere with each other and cause errors. This is also known as crosstalk.

A common method of dealing with these design considerations is to stack multiple PCB by bonding separately etched boards together. This allows creation of a single multi-layer PCB with 4, 6, 8 or more separate layers that are bonded together. The use of power and ground layers in additional stacks reduces the inductive or capacitive coupling that causes crosstalk interference between lines, and provides more two dimensional routing space to space lines further apart. While this process makes the design issues discussed above less problematic, use of a greater number of layers can significantly increase the costs.

In current DDR2 systems operating at about 800 MB/s or higher, it is widely accepted that the use of a four layer PCB is the minimum that may be used in order to achieve acceptable performance. In many systems, the use of these four layer DDR2 modules are a significant part of the cost.

As such, there is a need for a more cost effective method of achieving the performance given by current four or more layer DDR2 modules.

### SUMMARY OF THE INVENTION

The present invention provides a circuit board assembly for use in a memory system including a controller and a memory chip. In the circuit board, there is a top layer and a bottom layer, and the top layer includes a reserved memory chip space and a reserved controller space. The circuit board further includes a first set of no via data lines that connect a first set of points of the reserved controller space to a first set of points of the reserved memory chip space, and a set of secondary lines that connect a second set of points of the reserved controller space to a second set of points of the reserved memory chip space. The assembly also includes one or more sub-PCBs and each of the one or more sub-PCBs comprises an electrical plane. The first set of no via data lines and the set of secondary lines are substantially covered by the one or more sub-PCBs. Additionally, a first set of points of the controller and a first set of points of the memory chip are optimistically laid out to allow substantially direct connections from the first set of points of the controller to the second set of points of the memory chip along the set of no via data lines.

In another embodiment, the invention provides for a DDR2 SDRAM memory system comprising a two layer PCB comprising a top layer and a bottom layer; a controller attached to the top layer of the two layer PCB; a memory chip attached to the top layer of the two layer PCB; a first set of no via data lines that connect a first set of pins of the controller to a first set of pins of the memory chip; a set of secondary lines that connect a second set of pins of the controller to a second set of pins of the memory chip; and one or more sub-PCBs. Each of the one or more sub-PCBs comprises an electrical plane, and the memory chip operates at a frequency of about 400 MHz or above. Additionally, the first set of no via data lines and the set of secondary lines are substantially covered by the one or more sub-PCBs and the first set of pins of the controller and the first set of pins of the memory chip are optimistically laid out to allow substantially direct connections from the first set of pins to the second set of pins along the set of no via data lines.

In another embodiment, the invention provides for a method of creating a DDR2 SDRAM memory system. The method includes providing a DDR2 SDRAM memory controller and a DDR2 SDRAM memory chip such that a first set of pins of the DDR2 SDRAM memory controller and a first set of pins of the SDRAM memory chip are optimistically laid out, providing a two layer printed circuit board (PCB) with a first set of traces running along a first layer of the two layer board for connecting the first set of pins of the DDR2 SDRAM memory controller to the first set of pins of the SDRAM memory chip, attaching the DDR2 SDRAM memory controller and the DDR2 SDRAM memory chip to the first set of traces on the first layer of the two layer board, and substantially covering the first set of traces with an electrical plane.

In another embodiment, the invention provides a method of connecting a first set of pins of a memory controller and a first set of pins of a memory chip. The memory chip operates with a clock frequency above about 400 MHz, and the method involves creating a two layer printed circuit board (PCB) with a first set of traces running along a first layer of the PCB for connecting the first set of pins of the memory controller to the first set of pins of the memory chip, attaching the memory controller and the memory chip to the first set of traces on the first layer of the two layer board, and substantially covering the first set of traces with a sub-PCB.

In another embodiment the invention provides a DDR2 SDRAM memory system with a two layer PCB comprising a top layer and a bottom layer, a controller attached to the top layer of the two layer PCB, a memory chip attached to the top layer of the two layer PCB, a first set of no via data lines that connect a first set of pins of the controller to a first set of pins of the memory chip, and a set of secondary lines that connect a second set of pins of the controller to a second set of pins of the memory chip. Additionally, there are one or more sub-PCBs, and each of the one or more sub-PCBs comprises an electrical plane. The first set of no via data lines and the set of secondary lines are substantially covered by the one or more sub-PCBs, and the first set of pins of the controller and the first set of pins of the memory chip are optimistically laid out to allow substantially direct connections from the first set of pins to the second set of pins along the set of no via data lines.

### BRIEF DESCRIPTION OF THE DRAWINGS

The accompanying drawings, which constitute a part of this specification, illustrate various implementations of the present innovations and, together with the description, explain the principles of the innovations. In the drawings:

FIG. 1 is an illustration of a memory system with aspects of the innovations herein;

FIG. 2 is an illustration of a memory system with aspects of the innovations herein;

FIG. 3 is an illustration of a 2 layer PCB with a sub-PCB consistent with aspects of the innovations herein;

FIG. 4 is an illustration of a memory system with aspects of the innovations herein;

FIG. 5 shows a instrument reading of the impedance of a line on a two layer board where the line is substantially covered by a sub-PCB.

### DETAILED DESCRIPTION OF EXEMPLARY IMPLEMENTATIONS

The present invention will now be described in detail with reference to the drawings, which are provided as illustrative examples of the invention so as to enable those skilled in the art to practice the invention. The present invention may be implemented in a variety of forms, including the use of software, hardware, and/or firmware or any combination thereof, as would be apparent to those of ordinary skill in the art. The preferred embodiment of the present invention will be described herein with reference to an exemplary implementation of a DDR2 SDRAM memory system. However, the present invention is not limited to this exemplary implementation, but can be practiced in any computing system or device that includes high speed memory access in a chip on printed circuit board (PCB) environment. The exemplary implementation includes a first SDRAM chip 10 and a second SDRAM chip 12, but the present invention is not limited to this number of memory chips, and may use any number or combination of memory chips that may be placed in a system.

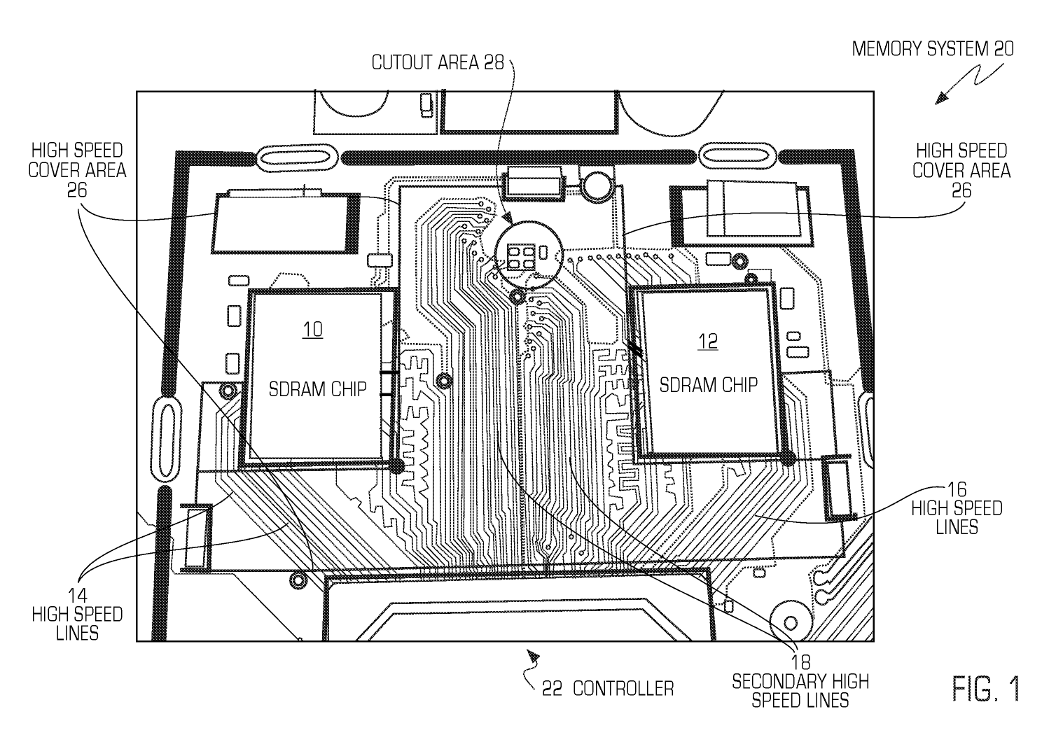

Referring now to FIG. 1, there is shown a front side perspective of an exemplary memory system 20. In one embodiment, memory system 20 includes a first SDRAM chip 10, a second SDRAM chip 12, a first set of high speed lines 14, a second set of high speed lines 16, an SDRAM controller chip 22, a set of secondary high speed lines 18, one or more, cut out area 28 and a high speed cover area 26.

First SDRAM chip 10 and second SDRAM chip 12 are solid state computer memory chips with data inputs and clock synchronizing inputs. The operation is synchronized with the rest of the device, including the SDRAM controller chip 22 through a clock signal that will typically be input by the set of secondary high speed lines 18. The SDRAM chips 10 and 12 operate at a frequency and bit rate such that data and clock lines on a single stand-alone PCB layer will interfere with each other. A typical operating frequency will be about 400 MHz or higher. The SDRAM chips may comply with JEDEC standards covering the interoperability of SDRAM.

The first set of high speed lines 14 and second set of high speed lines 16 connect the controller chip 22 to the respective memory chips. The first set of high speed lines 14 includes a line for carrying data and data strobe inputs and outputs. In order to further protect the signal integrity of the data, these lines may be structured to not have any via connections. In this exemplary embodiment, the data signal comes from the SDRAM controller 22 through a BGA ball connection to a line in the first set of high speed lines 14, which traces along the surface of the top layer of the memory system 20 shown in FIG. 1, and attaches to the SDRAM chip 10 through a ball connection.

The direct tracing from SDRAM controller 22 to SDRAM chip 10 has an optimistic matching set of connections. Because the lines are confined to a single layer, random layout of the chip connections will most likely lead to the lines within the set of high speed lines 14 having to cross or loop in order to connect to the appropriate corresponding connection on the corresponding chip. The optimistic layout of the chip pin out means that the lines in the set of high speed lines 14 may follow a path to limit crosstalk and provide acceptable signal integrity performance while connecting the pin outs of the SDRAM controller 22 and SDRAM chip 10. An optimistic layout limits, but does not necessarily eliminate, a need to detour or wrap lines around other lines or pins in order to make pin connections. One embodiment of the innovations herein includes only the first SDRAM chip 10, and no second SDRAM chip 12, using the rules described here.

For the embodiment shown in FIG. 1, the same optimistic layout applies to the pin outs of SDRAM controller 22 and corresponding pin out on SDRAM chip 12. Similarly, additional embodiments of the innovations herein include additional SDRAM chips and additional sets of high speed lines connecting the additional SDRAM chips with a controller. For each additional SDRAM chip, the same optimistic matching of pin outs applies.

SDRAM controller chip 22 is a chip that manages the flow of data going to and from SDRAM chip 10 and SDRAM chip 12. It is mounted on the top layer of the two layer board in memory system 20, which is the same layer where SDRAM chip 10 and SDRAM chip 12 are mounted. The connection between SDRAM controller chip 22 and the first layer will typically be a grid array of controlled collapse solder balls, but may be any electrical connection capable of an optimistic pin out connection with high signal integrity signal launch into lines such as high speed lines 14.

The first set of secondary high speed lines 18 include lines for carrying clock signals from SDRAM controller 22 to SDRAM chip 10 and SDRAM chip 12. Secondary high speed lines 18 are similar to the set of high speed lines 14 in that there are signal integrity issues with carrying high frequency signals. Because the clock signal is more repetitive and known, though, there is slightly more tolerance with secondary high speed lines 18, and they may include vias as well as portions of the lines on the second layer of the two layer PCB. Since the same clock signal may be used for clocking multiple chips, portions of the same line from the set of secondary high speed lines 18 may be transmitting a clock to multiple SDRAM chips. In FIG. 1, the clock signal leaves SDRAM controller 22 and travels along a line of secondary high speed lines 18 to a via. The signal then travels through the via to the second layer of the dual layer PCB, where the line splits, with one portion traveling to SDRAM chip 10 while the other portion travels to SDRAM chip 12. The clock line of secondary high speed lines 18, including the portions on the first layer and the second layer of the dual layer PCB, therefore generally makes a T shape.

In one embodiment, memory system 20 includes mounting points that are comprised of are copper pads for creating a solder attachment to the sub-PCB. The mounting points may additionally serve the purpose of extending the electrical ground of the system to a ground plane on the sub-PCB.

High speed cover area 26 serves as a mounting area for a sub-PCB. High speed cover area 26 substantially includes the area on the first layer of the dual layer PCB that includes the first set of high speed lines 14, the second set of high speed lines 16, and the set of secondary high speed lines 18. The high speed cover area is substantially flat, though it may include cut out areas such as cut out area 28. This allows components that are not substantially flat to be placed in an area surrounded by high speed transfer lines and the high speed cover area 26.

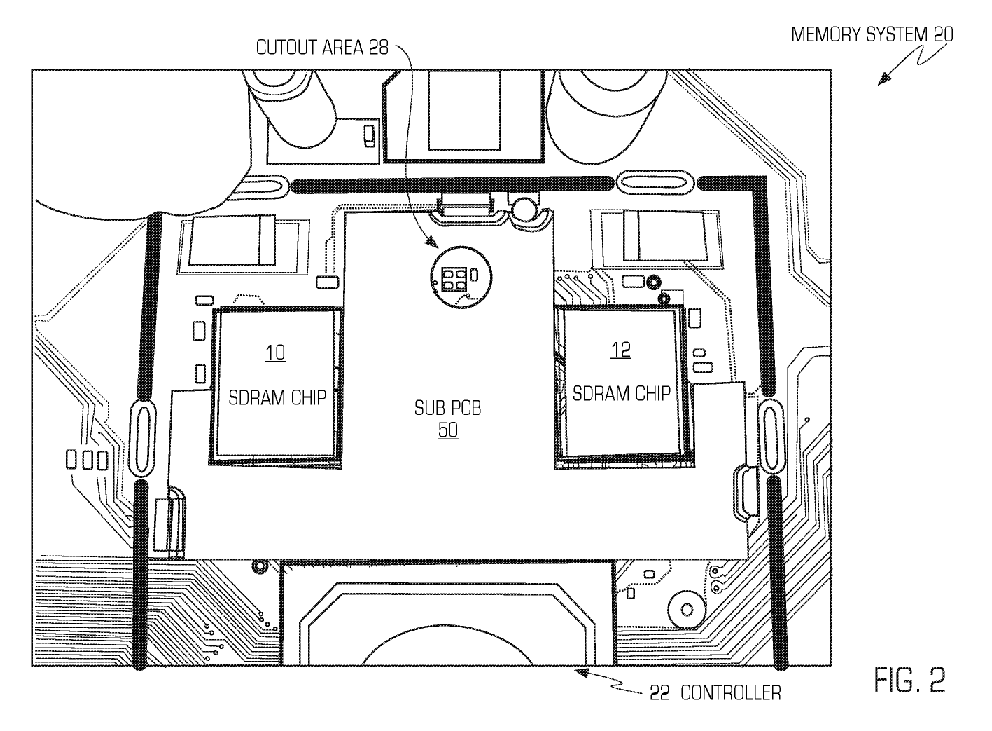

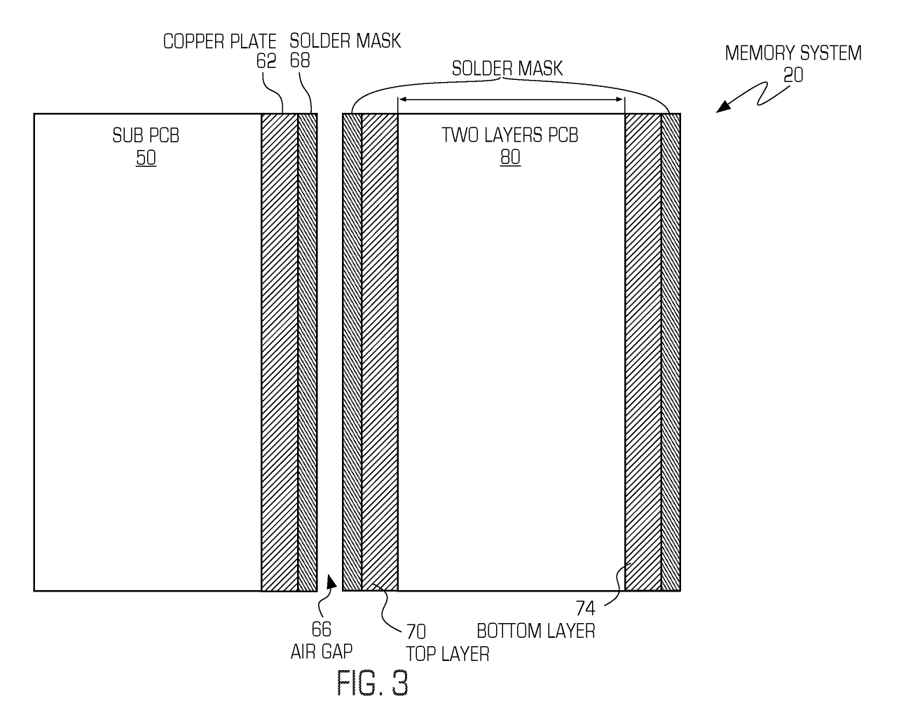

Memory system 20 in FIG. 2 shows sub-PCB 50 covering a high speed cover area. FIG. 2 also includes SDRAM Chip 10, SDRAM chip 12, SDRAM controller 22 and cut out area 28. Sub-PCB 50 is described further in relation to FIG. 3. All other components of memory system 20 are similar to the components of FIG. 1.

FIG. 3 shows memory system 20, comprising sub-PCB 50 next to two layer PCB 80, with air gap 66 in between. Sub-PCB 50 comprises copper plane 62 and solder mask 68. Two layer PCB 82 comprises top layer 70, bottom layer 74, and solder masks 72.

Sub-PCB 50 and two layer PCB 80 will typically have the same base material, such as FR4, though they may have different base materials. Copper plane 62 on sub-PCB 50 acts as a ground plane when placed next to top layer 70, and has the effect of a local impedance controlled by the presence of the ground plane. Top layer 70 is equivalent to the surface shown in FIG. 1, and contains the SDRAM controller and any SDRAM chips attached to the dual layer PCB. Solder mask 68 runs along certain portions of the Sub-PCB, and in combination with the top layer portion of solder mask 72, serves to provide a mechanical attachment from the Sub-PCB to the two layer PCB 80. Solder mask 68 and the top layer of solder mask 72 may also serve as an electrical connection between the two layer PCB 80 and the sub-PCB 50, allowing ground from two layer PCB 80 to extend to copper plane 62. Following attachment of the sub-PCB 50 to two layer PCB 80, a small air gap may remain in certain portions between the two. In order for the benefit of the innovations herein to function, the air gap should be in the order of about 0.7 mil or less. The attachment function served by solder mask 68 and the top layer of solder mask 72 may be served in any fashion that maintains this gap and also provides for a ground on the copper plane 62.

Bottom layer 74 serves as additional real estate for components and lines. For any secondary high speed lines, such as the clock lines described in FIG. 1, a second sub-PCB may be attached in the same manner as sub-PCB 50, but attached to the bottom layer 74 through the bottom layer of solder mask 74. The same tolerances and conditions apply for a bottom layer sub-PCB, as for the top layer sub-PCB 50.

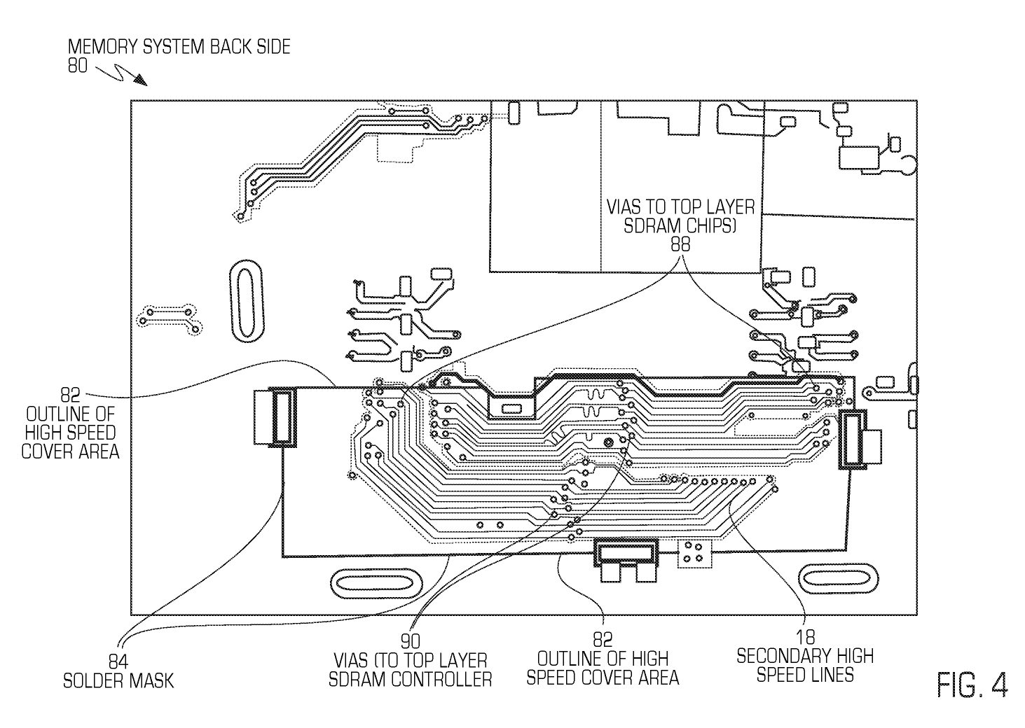

Memory system back side 80, shown in FIG. 4, shows an area set for placement of a bottom layer sub-PCB, and includes vias 88, vias 90, secondary high speed lines 18, an outline of high speed cover area 82, and solder mask 84.

Vias 88 lead to a subset of the pin out connections of SDRAM chips on the top layer of the dual layer PCB. Vias 90 are connected to an SDRAM controller on the top layer of the dual PCB. Vias 88 and 90 are connected by secondary high speed lines 18. A secondary high speed lines on the top layer of dual layer PCB will carry clock signals to certain of vias 90, and the clock signals will then travel over a subset of the secondary high speed lines 18 to vias 88, where the clock signals will pass back to the top layer, and then to the SDRAM chips attached to the top layer.

Just as described above, the high speed nature of secondary high speed lines 86 means that crosstalk issues may occur. Because of this, secondary high speed lines 86 will be substantially covered by a sub-PCB covering the area identified as the outline of high speed cover area 82. Solder mask 84 serves to attach the sub-PCB to the bottom layer, and the same rules apply for the bottom layer as described above for the top layer in FIGS. 1-3.

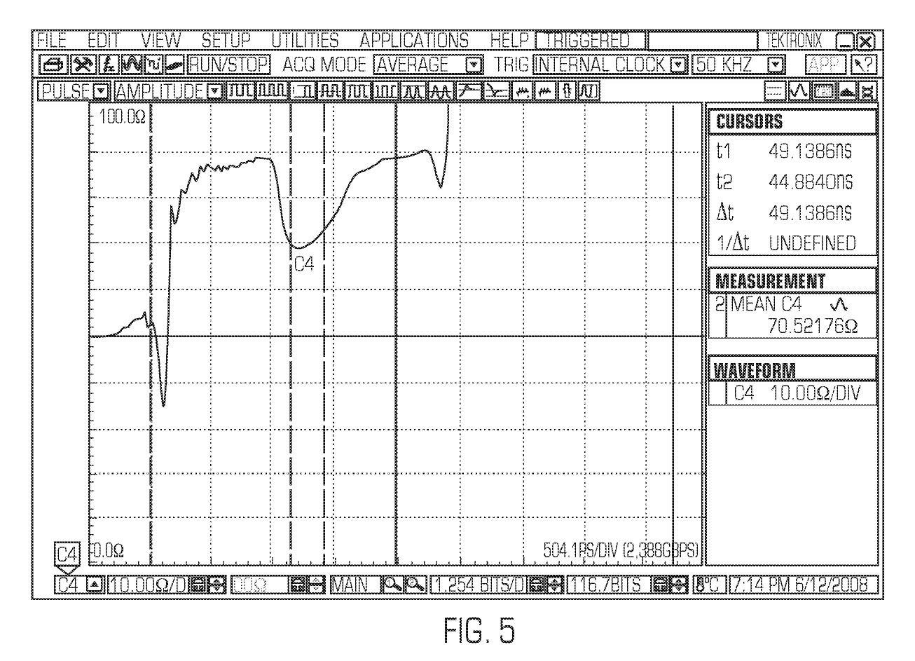

FIG. 5 shows the impact of a sub-PCB substantially covering a high speed line on a two layer board. Without the sub-PCB, the line measured approximately 88 ohms. With the electrical plane of the sub-PCB in proximity to the line, the line measures a mean value of approximately 70.5 ohms. Any gap between a sub-PCBs and the surface of the PCB layer with the line will impact the change in the qualities of the line. In one embodiment of the invention, a gap of less than about 0.7 mils permits for stable operation of the memory system. Depending on the shape of the electrical plane and other variations, certain embodiments may allow a gap variation in the range of this value. Because of the frequency dependent nature of crosstalk, embodiments of the invention do not provide a benefit at low frequency levels, and so the benefit is obtained at or above frequencies at which crosstalk for a particular design becomes an issue. FIG. 5 shows measurements for the frequency range from roughly 200 to 250 MHz. In one exemplary implementation, the memory chip in the invention operates at a clock rate of about 400 MHz or above, which is equivalent to the clock rate of DDR2-800.

Other implementations of the innovations herein will be apparent to those skilled in the art from consideration of the specification and practice of the innovations herein disclosed herein. It is intended that the specification and examples be considered as exemplary only, with a true scope and spirit of the innovations herein being indicated by the disclosure above in combination with the following paragraphs describing the scope of one or more implementations of the following innovations herein.

What is claimed is:

1. A circuit board assembly for use in a memory system including a controller and a memory chip comprising:
a two layer printed circuit board (PCB) comprising a top layer and a bottom layer, wherein the top layer comprises a reserved memory chip space and a reserved controller space;
a first set of no via data lines that connect a first set of points of the reserved controller space to a first set of points of the reserved memory chip space; and
a set of secondary lines that connect a second set of points of the reserved controller space to a second set of points of the reserved memory chip space; and
one or more sub-PCBs;
wherein each of the one or more sub-PCBs comprises an electrical plane;
the first set of no via data lines and the set of secondary lines are substantially covered by the one or more sub-PCBs; and
a first set of points of the controller and a first set of points of the memory chip are optimistically laid out to allow substantially direct connections from the first set of points of the controller to the second set of points of the memory chip along the set of no via data lines.

2. The memory system of claim 1 wherein the top layer further comprises
a second reserved memory chip space.

3. The memory system of claim 2 further comprising:
a second set of no via data lines that connect a third set of points of the reserved controller space to a first set of points of the second reserved memory chip space; and
wherein the set of secondary lines connects the second set of points of the controller to a second set of points of the second reserved memory chip space; and
the second set of no via data lines are substantially covered by the one or more sub-PCBs.

4. The memory system of claim 3 wherein a gap between each of the one or more sub-PCBs and a surface of the bottom layer over the set of secondary lines is less than about 1.5 mils.

5. The memory system of claim 1 wherein a gap between each of the one or more sub-PCBs and a surface of the top layer over the first set of no via data lines and the set of secondary lines is less than about 0.7 mils.

6. The memory system of claim 5 wherein a gap between each of the one or more sub-PCBs and a surface of the bottom layer over the set of secondary lines is less than about 0.7 mils.

7. The memory system of claim 1 wherein a portion of the secondary set of lines on the top layer and a portion of the secondary set of lines on the bottom layer generally form a T shape.

8. The memory system of claim 1 wherein a portion of the secondary set of lines on the top layer and a portion of the secondary set of lines on the bottom layer generally form a U shape.

9. A DDR2 SDRAM memory system comprising:
a two layer PCB comprising a top layer and a bottom layer;
a controller attached to the top layer of the two layer PCB;
a memory chip attached to the top layer of the two layer PCB;
a first set of no via data lines that connect a first set of pins of the controller to a first set of pins of the memory chip;
a set of secondary lines that connect a second set of pins of the controller to a second set of pins of the memory chip; and
one or more sub-PCBs;
wherein each of the one or more sub-PCBs comprises an electrical plane;
the memory chip operates at a frequency of about 400 MHz or above;
the first set of no via data lines and the set of secondary lines are substantially covered by the one or more sub-PCBs;
the first set of pins of the controller and the first set of pins of the memory chip are optimistically laid out to allow substantially direct connections from the first set of pins to the second set of pins along the set of no via data lines.

10. The DDR2 SDRAM memory system of claim 9 further comprising:
a second memory chip attached to the top layer of the two layer printed circuit board (PCB); and
a second set of no via data lines that connect a third set of pins of the controller to a first set of pins of the second memory chip;
wherein the set of secondary lines connects the second set of pins of the controller to a second set of pins of the second memory chip; and
the second set of no via data lines are substantially covered by the one or more sub-PCBs.

11. The DDR2 SDRAM memory system of claim 10 wherein a gap between each of the one or more sub-PCBs and a surface of the top layer over the first set of no via data lines, the second set of no via data lines and the set of secondary lines is less than about 1.5 mils.

12. The DDR2 SDRAM memory system of claim 11 wherein a gap between each of the one or more sub-PCBs and a surface of the bottom layer over the set of secondary lines is less than about 1.5 mils.

13. The DDR2 SDRAM memory system of claim 10 wherein a gap between each of the one or more sub-PCBs and a surface of the top layer over the first set of no via data lines, the second set of no via data lines and the set of secondary lines is less than about 0.7 mils.

14. The DDR2 SDRAM memory system of claim 13 wherein a gap between each of the one or more sub-PCBs and a surface of the bottom layer over the set of secondary lines is less than about 0.7 mils.

15. A method of creating a DDR2 SDRAM memory system comprising:
providing a DDR2 SDRAM memory controller and a DDR2 SDRAM memory chip such that a first set of pins of the DDR2 SDRAM memory controller and a first set of pins of the SDRAM memory chip are optimistically laid out;
providing a two layer printed circuit board (PCB) with a first set of traces running along a first layer of the two layer board for connecting the first set of pins of the DDR2 SDRAM memory controller to the first set of pins of the SDRAM memory chip;
attaching the DDR2 SDRAM memory controller and the DDR2 SDRAM memory chip to the first set of traces on the first layer of the two layer board; and
substantially covering the first set of traces with an electrical plane.

16. The method of claim 15 further comprising creating the DDR2 SDRAM memory chip to operate at a frequency greater than about 400 MHz.

17. The method of claim 15 wherein the electrical plane is a ground plane

18. The method of claim 15 wherein the electrical plane is a power plane.

19. A method of connecting a first set of pins of a memory controller and a first set of pins of a memory chip, wherein the memory chip operates with a clock frequency above about 400 MHz, comprising:
creating a two layer printed circuit board (PCB) with a first set of traces running along a first layer of the PCB for connecting the first set of pins of the memory controller to the first set of pins of the memory chip;
attaching the memory controller and the memory chip to the first set of traces on the first layer of the two layer board; and
substantially covering the first set of traces with a sub-PCB.

20. The method of claim 19 further comprising creating the memory chip to operate at a frequency greater than about 400 MHz.

21. A DDR2 SDRAM memory system comprising:
a two layer PCB comprising a top layer and a bottom layer;
a controller attached to the top layer of the two layer PCB;
a memory chip attached to the top layer of the two layer PCB;
a first set of no via data lines that connect a first set of pins of the controller to a first set of pins of the memory chip; and
a set of secondary lines that connect a second set of pins of the controller to a second set of pins of the memory chip; and
one or more sub-PCBs;
wherein each of the one or more sub-PCBs comprises an electrical plane;
the first set of no via data lines and the set of secondary lines are substantially covered by the one or more sub-PCBs;
the first set of pins of the controller and the first set of pins of the memory chip are optimistically laid out to allow substantially direct connections from the first set of pins to the second set of pins along the set of no via data lines.

22. The DDR2 SDRAM memory system of claim 21 further comprising:
a second memory chip attached to the top layer of the two layer PCB; and
a second set of no via data lines that connect a third set of pins of the controller to a first set of pins of the second memory chip;
wherein the set of secondary lines connects the second set of pins of the controller to a second set of pins of the second memory chip; and
the second set of no via data lines are substantially covered by the one or more sub-PCBs.

23. The DDR2 SDRAM memory system of claim 21 wherein a gap between each of the one or more sub-PCBs and a surface of the top layer over the first set of no via data lines and the set of secondary lines is less than about 1.5 mils.

24. The DDR2 SDRAM memory system of claim 23 wherein a gap between each of the one or more sub-PCBs and a surface of the bottom layer over the set of secondary lines is less than about 1.5 mils.

25. The DDR2 SDRAM memory system of claim 21 wherein a gap between each of the one or more sub-PCBs and a surface of the top layer over the first set of no via data lines and the set of secondary lines is less than about 0.7 mils.

26. The DDR2 SDRAM memory system of claim 25 wherein a gap between each of the one or more sub-PCBs and a surface of the bottom layer over the set of secondary lines is less than about 0.7 mils.

27. The DDR2 SDRAM memory system of claim 21 wherein the memory chip operates at a clock frequency above about 200 MHz.

28. The DDR2 SDRAM memory system of claim 21 wherein the memory chip operates at a clock frequency above about 400 MHz.
